(19) United States
(12) Patent Application Publication
(10) Pub. No.: US 2014/0366566 A1
(43) Pub. Date: Dec. 18, 2014

(54) CONTAINER DATA CENTER ASSEMBLY

(71) Applicant: HON HAI PRECISION INDUSTRY CO., LTD., New Taipei (TW)

(72) Inventor: CHAO-KE WEI, New Taipei (TW)

(73) Assignee: HON HAI PRECISION INDUSTRY CO., LTD., New Taipei (TW)

(21) Appl. No.: 13/971,865

(22) Filed: Aug. 21, 2013

(30) Foreign Application Priority Data
Jun. 14, 2013 (TW) 102121033

(51) Int. Cl. H05K 7/20

(52) U.S. Cl. CPC H05K 7/2029
USPC 62/259.2

(57) ABSTRACT

A container data center assembly takes account of ambient temperatures as well as the amount of heat generated by working servers includes a first and second and third circulatory cooling systems and a cooling tower. When the cooling tower can itself be cooled by the ambient temperature to a temperature less than a preset value, the third circulatory cooling system operates only to cool a server rack. When the cooling tower is heated by the ambient temperature or by the high temperature of returning coolant to a temperature equal to or greater than the preset value, the first circulatory cooling system operates to cool the server rack, and the second circulatory cooling system operates to cool a heat dissipating module.

### BACKGROUND

1. Technical Field

The present disclosure relates to container data center assemblies.

2. Description of Related Art

Servers in a container data center generate a lot of heat during operation. A common method for dissipating the heat is to arrange a refrigerating machine for every one of the servers, which uses and wastes a lot of energy.

### BRIEF DESCRIPTION OF THE DRAWINGS

Many aspects of the present embodiments can be better understood with reference to the following drawing. The components in the drawing are not necessarily drawn to scale, the emphasis instead being placed upon clearly illustrating the principles of the present embodiments. Moreover, in the drawing, like reference numerals designate corresponding parts throughout the several views.

FIG. 1 is a schematic block diagram of a container data center assembly.

FIG. 2 is a schematic block diagram of a controlling system of the container data center assembly of FIG. 1.

### DETAILED DESCRIPTION

The disclosure, including the accompanying drawing, is illustrated by way of examples and not by way of limitation. It should be noted that references to “an” or “one” embodiment in this disclosure are not necessarily to the same embodiment, and such references mean “at least one.”

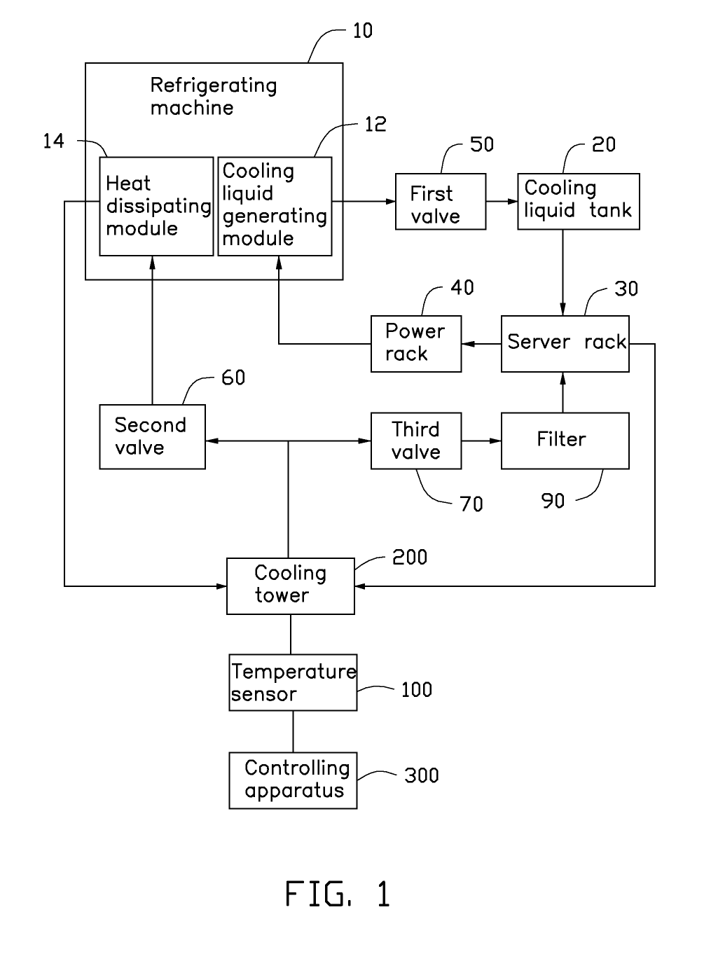

Referring to FIG. 1, an embodiment of a container data center assembly includes a refrigerating machine 10 for generating cooling liquid, a cooling liquid tank 20 for receiving the cooling liquid generated by the refrigerating machine 10, a server rack 30, a power rack 40 for providing power for the server rack 30, a first valve 50, a second valve 60, a third valve 70, a filter 90, a temperature sensor 100, a cooling tower 200, and a controlling apparatus 300. The refrigerating machine 10 includes a cooling liquid generating module 12 and a heat dissipating module 14 for cooling the cooling liquid generating module 12. In this embodiment, the cooling tower 200 stores normal temperature water as use as cooling liquid. The first valve 50, the second valve 60, and the third valve 70 are solenoid valves.

The cooling liquid generating module 12, the first valve 50, the cooling liquid tank 20, the server rack 30, and the power rack 40 are connected end to end in that order by pipes to form a first circulatory cooling system. When the first valve 50 is opened, the cooling liquid generated by the cooling liquid generating module 12 is directed to the server rack 30 for cooling the server rack 30, and then to the power rack 40 for cooling the power rack 40, and then back to the cooling liquid generating module 12.

The cooling tower 200, the second valve 60, and the heat dissipating module 14 are connected end to end in that order by pipes to form a second circulatory cooling system. When the second valve 60 is opened, the cooling liquid received in the cooling tower 200 flows through the second valve 60 to the heat dissipating module 14 for cooling the heat dissipating module 14, and then back to the cooling tower 200.

The cooling tower 200, the third valve 70, the filter 90, and the server rack 30 are connected end to end in that order by pipes to form a third circulatory cooling system. The filter 90 filters particles and impurities from the cooling liquid directed from the cooling tower 200 to the server rack 30. When the third valve 70 is opened, the cooling liquid received in the cooling tower 200 flows through the third valve 70 and the filter 90 to the server rack 30 for cooling the server rack 30, and then back to the cooling tower 200.

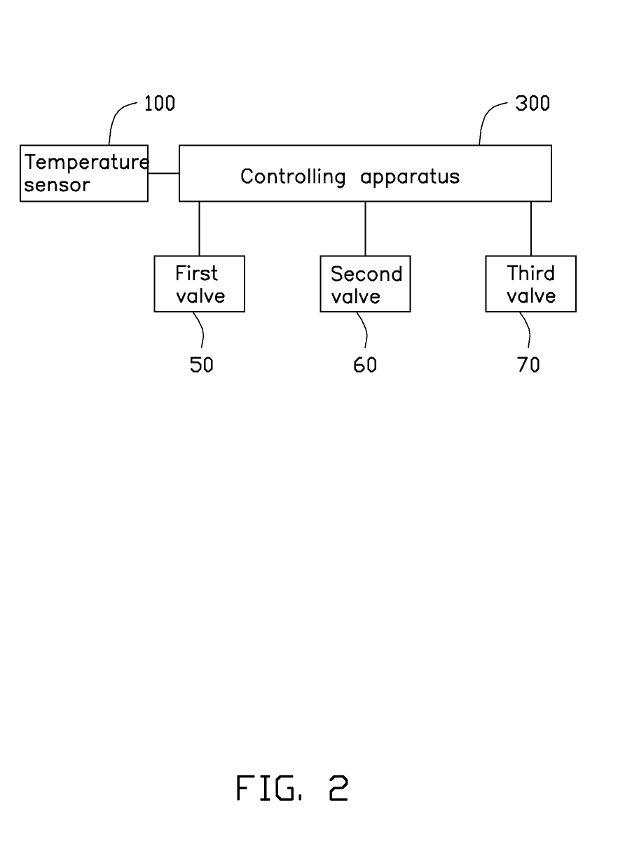

Referring to FIG. 2, the temperature sensor 100 is set in the cooling tower 200 for sensing the temperature of the water in the cooling tower 200. The temperature sensor 100 is connected to the controlling apparatus 300 and transfers signals to the controlling apparatus 300. The controlling apparatus 300 is connected to the first valve 50, the second valve 60, and the third valve 70, to control the states of the first, second, and third valves, 50, 60, and 70.

When the temperature of the cooling liquid in the cooling tower is greater than or equal to a preset value, such as 30 degrees Celsius, the temperature sensor 100 transfers a signal to the controlling apparatus 300. The controlling apparatus 300 controls the first valve 50 and the second valve 60 to open and controls the third valve 70 to close. The first circulatory cooling system operates to cool the server rack 30, and the second circulatory cooling system operates to cool the heat dissipating module 14.

When the temperature of the cooling liquid in the cooling tower is less than the preset value, the temperature sensor 100 transfers a signal to the controlling apparatus 300. The controlling apparatus 300 controls the first valve 50 and the second valve 60 to close and controls the third valve 70 to open, and the third circulatory cooling system operates to cool the server rack 30.

In the embodiment, the temperature of cooling liquid in the cooling tower 200 is variable according to the ambient or environmental temperature, thus in summer, for example, or when heat generated by the server rack 30 is great, the first circulatory cooling system is open to cool the server rack 30, and the second circulatory cooling system is open to cool the heat dissipating module 14. Conversely, in winter, for example, or when heat generated by the server rack 30 is small, the first circulatory cooling system and the second circulatory cooling system are closed to save energy, and only the third circulatory cooling system operates to cool the server rack 30.

Even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A container data center assembly comprising a refrigerating machine, a server rack, a first valve, a second valve, a third valve, and a cooling tower;
wherein the refrigerating machine comprises a cooling liquid generating module and a heat dissipating module for cooling the cooling liquid generating module;
wherein the cooling liquid generating module, the first valve, and the server rack are connected end to end in that order to form a first circulatory cooling system, when the first valve is opened, the cooling liquid generated by the cooling liquid generating module is directed to the server rack for cooling the server rack, and then back to the cooling liquid generating module;
wherein the cooling tower, the second valve, and the heat dissipating module are connected end to end in that order to form a second circulatory cooling system, when the second valve is opened, the cooling liquid received in the cooling tower flows through the second valve to the heat dissipating module for cooling the heat dissipating module, and then back to the cooling tower;
wherein the cooling tower, the third valve, and the server rack are connected end to end in that order to form a third circulatory cooling system, when the third valve is opened, the cooling liquid received in the cooling tower flows through the third valve to the server rack for cooling the server rack, and then back to the cooling tower;
wherein when cooling liquid in the cooling tower is greater than or equal to a preset value in temperature, the first valve and the second valve are opened and the third valve is closed, the first circulatory cooling system operates to cool the server rack, the second circulatory cooling system operates to cool the heat dissipating module; and
wherein when cooling liquid in the cooling tower is less than the preset value, the first valve and the second valve are closed and the third valve is opened, the third circulatory cooling system operates to cool the server rack.

2. The container data center assembly of claim 1, further comprising a temperature sensor set in the cooling tower for sensing temperature of the cooling liquid in the cooling tower, and a controlling apparatus, the temperature sensor is connected to the controlling apparatus and transfers signals to the controlling apparatus, the controlling apparatus is connected to the first valve, the second valve, and the third valve, to control the first to third valves to open or close according to the signals of the temperature sensor.

3. The container data center assembly of claim 1, wherein first circulatory cooling system further comprises a cooling liquid tank connected between the first valve and the server rack.

4. The container data center assembly of claim 1, wherein first circulatory cooling system further comprises a power rack connected between the cooling liquid generating module and the server rack.

5. The container data center assembly of claim 1, wherein the third circulatory cooling system further comprises a filter connected between the third valve and the server rack.
